(19) United States
(12) Patent Application Publication
(10) Pub. No.: US 2021/0143817 A1
(43) Pub. Date: May 13, 2021

(54) Octave Bandwidth High Power Non-Reflective Shunt PIN Diode Switch

(71) Applicant: NATIONAL INSTRUMENTS CORPORATION, Austin, TX (US)

(72) Inventor: Justin R. Magers, Santa Rosa, CA (US)

(21) Appl. No.: 17/069,041

(22) Filed: Oct. 13, 2020

Related U.S. Application Data
(60) Provisional application No. 62/934,677, filed on Nov. 13, 2019.

(51) Int. Cl. H03K 17/76

(52) U.S. Cl. CPC H03K 17/76

(57) ABSTRACT

A low-reflectivity solid-state switch circuit includes an input port configured to transmit an electronic signal and first and second output ports configured to receive the electronic signal. The switch circuit further includes a first switching element connected between the input port and the first output port, a second switching element connected between the input port and the second output port, a third switching element connected to a first conductive path between the first switching element and the first output port, and a fourth switching element connected to a second conductive path between the second switching element and the second output port. The third and fourth switching elements are utilizable to shunt current reflections from their connected conducted paths when the respective conductive path is configured in an off configuration.

### PRIORITY INFORMATION

This application claims priority to U.S. Provisional Patent Application No. 62/934,677, titled “Octave Bandwidth High Power Non-Reflective Shunt PIN Diode Switch” and filed on Nov. 13, 2019, which is hereby incorporated by reference in its entirety, as though fully and completely set forth herein.

### BACKGROUND

An electrical switch may be used in a high frequency circuit to connect and disconnect an electrically conductive path within the circuit. Switching may be implemented in test and measurement systems to automate routing of signals from one device to another. For example, a measurement device (e.g., voltmeter) may be coupled to an output of a switch having a plurality of inputs each coupled to a respective device under test (DUT). During operation, the measurement device may be used to take measurements from each of the DUTs by sequentially opening and closing sets of switches, one after the other, to sequentially connect the inputs of the switch to outputs for each of the DUTs. Accordingly, switches may provide for simplified connectivity, such that a test system can easily and dynamically modify internal connection paths without external manual intervention (e.g., without a user having to physically re-route cabling between devices). Similar switching techniques may be used in various operations that require dynamic routing of signals between devices. Current high frequency measurement systems, however, use switches that may degrade the transmitted signal and/or introduce reflections on blocked paths. Accordingly, improvements in the field are desirable.

### SUMMARY

Described herein are embodiments relating to switching element systems, circuits, and methods. For example, in some embodiments, a switch circuit topology is provided that is at least partially implemented using positive-intrinsic-negative (PIN) diodes as switching elements. The switch circuit may include one or more inputs and one or more outputs, and may be selectively operable to close one or more paths between one or more of the inputs and the outputs, while opening one or more other paths. Selectively operating the switch may be performed via actuation by altering voltages across the diodes within the switch. For example, the switch may be selectively operable in a first state, wherein the circuit elements of the switch couple one of the plurality of inputs to one of the plurality of outputs such that a high frequency analog signal input to the respective input is routed to the respective output. The switch may also be selectively operable in a second state, wherein the same or another of the plurality of inputs is connected to another or the same of the plurality of outputs, respectively. In exemplary embodiments, PIN diode switching elements are utilized to provide a non-reflective shunt path to reduce reflections off the unselected arm of the switch circuit.

This Summary is intended to provide a brief overview of some of the subject matter described in this document. Accordingly, it will be appreciated that the above-described features are merely examples and should not be construed to narrow the scope or spirit of the subject matter described herein in any way. Other features, aspects, and advantages of the subject matter described herein will become apparent from the following Detailed Description, Figures, and Claims.

### BRIEF DESCRIPTION OF THE DRAWINGS

A better understanding of the present disclosure can be obtained when the following detailed description is considered in conjunction with the following drawings, in which:

FIG. 1 is a graph illustrating reflectivity of the port connected to the “open arm” of a typical Ka band shunt PIN diode switch, according to some embodiments;

FIGS. 2A-2B are detailed circuit diagrams illustrating exemplary PIN diode switch circuit topologies, according to some embodiments;

FIG. 3A is a simplified schematic illustration of a switch topology utilizing shunt paths and where the input is connected to output 1, according to some embodiments;

FIG. 3B is a simplified schematic illustration of the switch topology illustrated in FIG. 3A where both arms of the switch are open, according to some embodiments;

FIGS. 4A-4B illustrate a model of switch performance using a shunting PIN diode switch topology, according to some embodiments;

FIG. 5 illustrates a simplified PIN diode switch circuit diagram, enumerating exemplary characteristic impedances and electrical lengths for different transmission lines of the circuit diagram, according to some embodiments;

FIG. 6 is a simplified schematic illustration of FIG. 5 where the PIN diodes are replaced with ideal short circuits and open circuits to represent the low and high impedance states of the PIN diodes, according to some embodiments;

FIG. 7 illustrates a model of switch performance according to the simplified circuit model of FIG. 6, according to some embodiments;

FIG. 8 illustrates a layout of the gallium arsenide (GaAs) monolithic microwave integrated circuit (MIMIC) with shunting PIN diode switch topology, according to some embodiments;

FIG. 9 is a block diagram illustrating an example use case of a SPDT switch in a practical 5G test and measurement system, according to some embodiments;

FIGS. 10A-B are circuit diagrams illustrating the functionality of a forward-biased shunt PIN diode as a switching element, according to some embodiments; and

FIGS. 11A-B are circuit diagrams illustrating the functionality of a reverse-biased shunt PIN diode as a switching element, according to some embodiments.

While the disclosure is susceptible to various modifications and alternative forms, specific embodiments thereof are shown by way of example in the drawings and will herein be described in detail. It should be understood, however, that the drawings and detailed description thereto are not intended to limit the disclosure to the particular form disclosed, but on the contrary, the intention is to cover all modifications, equivalents, and alternatives falling within the spirit and scope of the present disclosure as defined by the appended claims. It is noted that the word “may” is used throughout this application in a permissive sense (e.g., having the potential to, being able to), not a mandatory sense (e.g., must).

### DETAILED DESCRIPTION

In the following description, numerous specific details are set forth to provide a thorough understanding of embodiments of the present disclosure. However, one having ordinary skill in the art should recognize that the disclosure may be practiced without these specific details. In some instances, well-known circuits, structures, and techniques have not been shown in detail to avoid obscuring the present disclosure.

This specification includes references to “one embodiment” or “an embodiment.” The appearances of the phrases “in one embodiment” or “in an embodiment” do not necessarily refer to the same embodiment. Particular features, structures, or characteristics may be combined in any suitable manner consistent with this disclosure.

### Terms

The following is a glossary of terms used in the present application:

Software Program—the term “software program” is intended to have the full breadth of its ordinary meaning, and includes any type of program instructions, code, script and/or data, or combinations thereof, that may be stored in a memory medium and executed by a processor. Exemplary software programs include programs written in text-based programming languages, such as C, C++, PASCAL, FORTRAN, COBOL, JAVA, assembly language, etc.; graphical programs (programs written in graphical programming languages); assembly language programs; programs that have been compiled to machine language; scripts; and other types of executable software. A software program may comprise two or more software programs that interoperate in some manner. Note that various embodiments described herein may be implemented by a computer or software program. A software program may be stored as program instructions on a memory medium.

Program—the term “program” is intended to have the full breadth of its ordinary meaning. The term “program” includes 1) a software program which may be stored in a memory and is executable by a processor or 2) a hardware configuration program usable for configuring a programmable hardware element.

Computer System—any of various types of computing or processing systems, including a personal computer system (PC), mainframe computer system, workstation, network appliance, Internet appliance, personal digital assistant (PDA), television system, grid computing system, or other device or combinations of devices. In general, the term “computer system” can be broadly defined to encompass any device (or combination of devices) having at least one processor that executes instructions from a memory medium.

Measurement Device—includes instruments, data acquisition devices, smart sensors, and any of various types of devices that are configured to acquire and/or store data. A measurement device may also optionally be further configured to analyze or process the acquired or stored data. Examples of a measurement device include an instrument, such as a traditional stand-alone “box” instrument, a computer-based instrument (instrument on a card) or external instrument, a data acquisition card, a device external to a computer that operates similarly to a data acquisition card, a smart sensor, one or more DAQ or measurement cards or modules in a chassis, an image acquisition device, such as an image acquisition (or machine vision) card (also called a video capture board) or smart camera, a motion control device, a robot having machine vision, and other similar types of devices. Exemplary “stand-alone” instruments include oscilloscopes, multimeters, signal analyzers, arbitrary waveform generators, spectroscopes, and similar measurement, test, or automation instruments.

A measurement device may be further configured to perform control functions, e.g., in response to analysis of the acquired or stored data. For example, the measurement device may send a control signal to an external system, such as a motion control system or to a sensor, in response to particular data. A measurement device may also be configured to perform automation functions, i.e., may receive and analyze data, and issue automation control signals in response.

Automatically—refers to an action or operation performed by a computer system (e.g., software executed by the computer system) or device (e.g., circuitry, programmable hardware elements, ASICs, etc.), without user input directly specifying or performing the action or operation. Thus the term “automatically” is in contrast to an operation being manually performed or specified by the user, where the user provides input to directly perform the operation. An automatic procedure may be initiated by input provided by the user, but the subsequent actions that are performed “automatically” are not specified by the user, i.e., are not performed “manually,” wherein the user specifies each action to perform. For example, a user filling out an electronic form by selecting each field and providing input specifying information (e.g., by typing information, selecting check boxes, radio selections, etc.) is filling out the form manually, even though the computer system must update the form in response to the user actions. The form may be automatically filled out by the computer system where the computer system (e.g., software executing on the computer system) analyzes the fields of the form and fills in the form without any user input specifying the answers to the fields. As indicated above, the user may invoke the automatic filling of the form, but is not involved in the actual filling of the form (e.g., the user is not manually specifying answers to fields but rather they are being automatically completed). The present specification provides various examples of operations being automatically performed in response to actions the user has taken.

Concurrent—refers to parallel execution or performance, where tasks, processes, or programs are performed in an at least partially overlapping manner. For example, concurrency may be implemented using “strong” or strict parallelism, where tasks are performed (at least partially) in parallel on respective computational elements, or using “weak parallelism,” where the tasks are performed in an interleaved manner, e.g., by time multiplexing of execution threads.

Approximately—refers to a value being within some specified tolerance or acceptable margin of error or uncertainty of a target value, where the specific tolerance or margin is generally dependent on the application. Thus, for example, in various applications or embodiments, the term approximately may mean: within 0.1% of the target value, within 0.2% of the target value, within 0.5% of the target value, within 1%, 2%, 5%, or 10% of the target value, and so forth, as required by the particular application of the present techniques.

Return Loss—in accordance with standard terminology in the art, “return loss” is referenced in positive decibels, and refers to the negative of reflectivity, wherein reflectivity is defined as the log of the ratio of the reflected power to the incident power in regard to a particular circuit network. Accordingly, a lower reflectivity network should exhibit a negative reflectivity with a larger magnitude, and correspondingly a larger positive return loss, than a higher reflectivity network.

Matched Network—refers to an electrical network with high return loss on all ports.

Non-reflective switch—refers to a switch capable of having a high return loss on all ports simultaneously.

Passive Network—refers to a network that does not apply a positive gain.

Lossless Network—refers to a network where no power is dissipated.

### DETAILED DESCRIPTION

As discussed in more detail below, certain embodiments include systems and methods relating to switches and/or switch circuits. The specification describes various switch circuit topologies that may be suited for use with the disclosed switches and switching techniques. The described switch topology of the Figures, as well as other switch topologies described herein, may be representative of the topology of a switch used to provide a connection between a plurality of input ports and output ports.

In some embodiments, within a switch circuit, each of a plurality of switching elements (e.g., PIN diode switching elements) is coupled to one or more other switching elements via interconnects. It is noted here that “switching element” as used herein is intended to refer to the individual PIN diode switching elements that are used within the described switch circuits, while “switch”, “switch circuit”, or “solid-state switch” refers to the overall switch circuit, which may contain a plurality of switching elements. Interconnects may include a conductive path that provides for the routing of an electrical signal between two elements/components. For example, interconnects may include a conductive (e.g., metal) trace located on a printed wiring board (PWB), a printed circuit board (PCB) or a monolithic microwave integrated circuit (MMIC), among other possibilities. As depicted, interconnects may couple an output (e.g., output terminal) of one of the switching elements to an input (e.g., input terminal) of another one of the switching elements. Interconnects may also be provided to couple inputs to inputs of switching elements and/or outputs to outputs of switching elements. In some embodiments, the interconnects may be incorporated within the switching elements themselves, such that they do not need to be separately incorporated as additional circuit elements.

Switching elements the same or similar to those described herein may be employed in a variety of schemes to provide for routing of signals. In some embodiments, for example, shunt switching elements may be employed to provide a switch having desired (i.e., low) signal reflectivity on the off path. One type of switching element that may be used in the described topologies includes diode switches such as positive-intrinsic-negative (PIN) diode switches. Although the switches below are described as being partially implemented in a monolithic microwave integrated circuit (MMIC), the switching structures and techniques described herein apply to similar laminated materials as well. For example, the switches described according to embodiments herein may be implemented on a printed circuit board (PCB), a printed wiring board (PWB), or other laminated or co-fired materials for lower frequency applications.

### Solid-State Switch Topologies

There are many different technologies and applications in which solid-state switches operate at microwave and/or millimeter-wave frequencies. In these applications, switches realized with positive-intrinsic-negative (PIN) diodes may be selected for their ability to handle signals with high power, exhibit low loss, and maintain high linearity (e.g., low distortion).

Typical PIN diode switches may be implemented with series and/or shunt diodes, according to previous implementations. PIN diode switches implemented with only shunt diodes may exhibit high power handling, high linearity, and low loss compared to other PIN diode designs since the “closed arm” of the switch has only reverse bias diodes in the signal path. In contrast, switches with series diode(s) in the “closed arm” may be limited by the distortion and power handling of the series diode(s).

Another desirable feature of a high frequency switch is that the “open port” of the switch does not reflect signals, i.e. that it exhibits a high return loss. This is known as a “non-reflective” switch. While some current PIN diode switch implementations are classified as “non-reflective,” their return loss is typically less than 10 dB for much of the octave-wide band, which may be too reflective for many reflection-sensitive applications. For example, FIG. 1 illustrates return loss for a typical PIN diode switch in the “open” state, which exhibits return loss well below 20 dB throughout the octave frequency range from 20 GHz to 40 GHz. As used herein, “open” refers to a state of a switching element where the switching element does not allow current to flow between two portions of a circuit, as shown for switching element 1002 in FIG. 10B, whereas “closed” refers to a state of a switching element where the switching element does allow current to flow between two portions of a circuit, as shown for switching element 1102 in FIG. 11B.

Note that, in accordance with standard terminology in the art, “return loss” is referenced in positive decibels, and is defined as the negative of reflectivity, wherein reflectivity is defined as the log of the ratio of the reflected power to the incident power in regard to a particular circuit element. Note that reflectivity is illustrated in FIG. 1. Accordingly, a lower reflectivity switch should exhibit a negative reflectivity with a larger magnitude, and correspondingly a larger positive return loss, than a higher reflectivity switch.

In these implementations, a low (poor) return loss may be a consequence of the switch topology rather than poor design, poor implementation, or poor process control and/or fabrication. For test and measurement applications (for example, in the area of 5G New Radio (NR) testing for semiconductor devices), maintaining a return loss of greater than 20 dB over an octave may be very desirable on device-under-test (DUT) facing ports. In addition, it may be desirable to minimize reflections on the internal signal paths inside electronic equipment for tasks such as terminating reflectometer ports and high gain amplifiers.

In order to improve upon these prior implementations, embodiments herein present a non-reflective shunt PIN switch circuit topology to address these and other concerns.

### Technological Applicability

5G DUTs that interface with phased array antennas (an important enabling technology for 5G) may have many ports. While it's possible for a 5G tester to have a transmitter and a receiver for every DUT port, this may be undesirably expensive. A more economic approach may be to have a single transmitter and receiver for the 5G tester, and to use switches to route the signals from many DUT ports into and out of the single receiver and transmitter, respectively. For example, the National Instruments (NI) 5G mmWave VST™ contains a plurality of many single-pole double-throw (SPDT) switches for this purpose. For example, the bottom mmWave head of the NI 5G mmWave VST™ has 16 ports that come into a single transceiver (transmitter+receiver). The 16 port switch is realized with a “tree” of 14 SPDT PIN switches. Alternatively, similar systems using SDPT PIN switches may be utilized in a Semiconductor Test System (STS) such as the Advantest V93000™ and the Teredyne UltraWaveMX44™, which may likewise be configured with a large number of ports. These and other testing devices may exhibit improved functionality by employing high return loss PIN diode switch topologies such as those described herein, according to various embodiments. For example, it may be desirable to have a high return loss on the “open” arm of a diode switch which is connected to the DUT, to enhance the testing fidelity of these and other testing systems.

These types of testing systems may be used to test 5G smartphones, base stations, and the integrated circuits inside them. Some of those DUTs may have very high power, particularly “Front End Modules (FEM)” that contain power amplifiers, which may have output power as high as 2 Watts (+33 dBm). Accordingly, it may be desirable for the test system to be able to handle high-power DUTs. Switch topologies described herein may further offer flexibility to allow a testing system to effectively test a high-power DUT, according to some embodiments.

Alternatively or additionally, in some embodiments, switch circuit topologies described herein may be employed within base stations, UE devices, satellite and point-to-point (P2P) communications systems, radar systems, radiometers, test and instrumentation equipment and other types of computing devices that operate using high frequency signals.

### FIGS. 2A-2B—Non-Reflective PIN Diode Switch Topology

FIG. 2A is a detailed circuit diagram illustrating an exemplary PIN diode switch circuit topology to implement a non-reflective shunt PIN diode switch, according to some embodiments. In FIG. 2A, capacitors, resistors, PIN diodes, and transmission lines that conductively connect adjacent circuit elements are illustrated as indicated by the legend. “Port” labels inputs and outputs of the switch, within the circuit. Other circuit elements follow standard notation.

An electric potential or voltage may be applied to the terminals denoted V1, V2, V3, and V4 to change the impedance between the anode and the cathode of the PIN diodes and thus alter the state of the switch PIN diode switching elements. The resistors R1, R2, R3, and R4 set the current passing through the PIN diodes when the diodes are forward biased. The passband of this switch, or the frequency range in which the switch has desirable characteristics such as low loss in the “on arm” and high return loss on the ports, is limited to roughly 1 octave and may be set according to the electrical lengths of the transmission lines. In other embodiments, other methods besides electrical resistance may be used for setting the current in forward biased diodes. For example, PIN diode driver circuits, op-amp circuits, specialty amplifiers such as clamp amplifiers or differential amplifiers, and/or charge pumps may be used to control the current in forward biased diodes, in various embodiments.

In FIG. 2A, the “on arm” of the switch is defined by the signal path from port 1 (also known as the “common port”) to port 3 when D_{2A}, D_{2B}, D_{3A}, and D_{3B} are forward biased such that they are in a low impedance state (i.e., such that the impedance between the anode and the cathode of the diode is low compared to the system characteristic impedance) and D_{1A}, D_{1B}, D_{4A}, and D_{4B} are reversed bias such that they are in a high impedance state (i.e., such that the impedance between the anode and cathode is large compared to the system characteristic impedance).

If the low impedance state of the PIN diodes are approximated as short circuits, the high impedance states are approximated as open circuits, the transmission lines are approximated as lossless, and the inductors are open circuits and capacitors are short circuits as shown in FIG. 6, then this passive network between port 1 and port 3 is lossless, reciprocal, and matched. Signals traveling on port 1 to port 3 may travel from port 3 to port 1.

The signal path between port 1 and port 2 is the “off arm” path of the switch in FIG. 6. In this configuration, signals incident on port 2 will be absorbed into the resistor having a resistance equal to the system characteristic impedance (typically around 50 Ohms, although other system characteristic impedances are also possible). Signals incident on port 2 will be absorbed into the resistor and not reflected.

The scattering parameters of the electrical schematic depicted in FIG. 6 is shown in FIG. 7. The traces in FIG. 7 were calculated while the circuit is in the configuration where the path from port 1 to port 3 is on, and the path between port 1 to port 2 is off. In FIG. 7, traces labeled as “S_{xy}” refer to the power ratio, in decibels, of the power received at the x port to the power transmitted into they port. For example, S₁₁ refers to the reflectivity at port 1, and S₂₁ refers to the ratio of power received at port 2 to power input to port 1. As illustrated, isolation is infinite since the low impedance PIN diodes are replaced with ideal short circuits. Further, the reflectivity at port 2 and port 3 remains well below −20 dB, and generally below −25 dB, for the octave frequency range from ˜23 GHz to ˜54 GHz.

By swapping the bias on the diodes (i.e. by forward biasing D_{1A}, D_{1B}, D_{3A}, D_{3B}, and reverse biasing D_{2A}, D_{2B}, D_{4A}, and D_{4B}), the state of the switch may be altered such that the signal path between port 1 and port 2 is the “on path” of the switch and the path between port 1 and port 3 is the “off path” of the switch. In this configuration, signals traveling on port 1 to port 2 may travel from port 2 to port 1.

Regardless of whether this switch is configured such that the “on path” is between port 1 and port 3 or is between port 1 and port 2, all ports of the switch have a high return loss (i.e., are not reflective). This is commonly known in the industry as a “non-reflective” switch. In contrast, a “reflective switch” has a high reflection (low return loss) on the non-common port connected to the “off path”. Both types of switches (reflective and non-reflective) exhibit low power loss in the “on path” and “high loss” (also known as isolation) on the “off path”. Additionally, both types of switches exhibit high signal loss between the non-common ports (port 2 and port 3).

Another useful configuration of this switch is when D_{1A}, D_{1B}, D_{2A}, and D_{2B} are forward biased and D_{3A}, D_{3B}, D_{4A}, and D_{4B} are reversed biased. In this state, both port 2 and port 3 exhibit high return loss and incident signal power is absorbed into R5 and R6. In contrast to the previously described states, in this configuration the paths from port 1 to port 3 and port 1 to port 2 simultaneously exhibit high isolation.

In some embodiments, a low-reflectivity solid-state switch includes an input port configured to transmit an electronic signal and a first output port and a second output port configured to receive the electronic signal. Alternatively, in some embodiments the switch may include multiple input ports and/or more than two output ports. In other words, embodiments described herein for shunting reflections using diode switch elements may be used by other types of switches besides SPDT switches, such as DPDT, DP4T, XPYT, or other types of switches.

FIG. 2B illustrates a switch circuit topology similar to FIG. 2A, except that four of the transmission lines are replaced by inductors, according to some embodiments. Advantageously, the illustrated placement of inductors within the switch circuit may selectively block high frequency alternating current signals from passing through the inductors, while allowing direct current (DC) signals to pass unaffected.

Schematic diagrams for switch circuits are illustrated in FIGS. 3A-3B. In FIG. 3A, the path between input 1 and output 1 is referred to as the “on arm” and the path between the input 1 and output 2 is referred to as the “off arm” of the switch. In some embodiments, as shown in FIGS. 3A-3B, the switch includes a first switching element 302 connected between the input port 314 and the first output port 316, a second switching element 304 connected between the input port 314 and the second output port 318, a third switching element 306 connected to a first conductive shunt path between the first switching element 302 and the first output port 310, and a fourth switching element 308 connected to a second conductive path between the second switching element 304 and the second output port 312.

In some embodiments, the switching elements are positive-intrinsic-negative (PIN) diode switches. Alternatively, the switching elements may be other types of semiconductor switches (e.g., GaAs field effective transistor (FET) switches), switches with other actuation methods, or other type of switches.

The solid-state switch may be configurable to close the first and fourth switching elements and open the second and third switching elements to enable a first connection for transmitting electronic signals between the input port and the first output port. In this configuration, the solid-state switch may further disable a second connection for transmitting electronic signals between the input port and the second output port. Alternatively, the solid-state switching element may be configurable to close the second and third switching elements and open the first and fourth switching elements to disable the first connection and enable the second connection.

Note that FIGS. 3A-3B illustrates a similar switch topology to FIGS. 2A-B, but in FIGS. 3A-3B many of the circuit elements are removed for clarity. As illustrated, the switch in FIG. 3A exhibits a single input port labeled “Input 1”, and two output ports labeled “Output 1” and “Output 2”. Further, four switching elements, which may be shunt PIN diode switching elements, are illustrated as arrows and labeled as 302-308 which correspond to the first through fourth switching elements described above, respectively. The straight lines in FIG. 3A represent conductive elements that connect adjacent circuit elements. Furthermore, two 50Ω resistors and two ground connections are illustrated using standard notation. The switch illustrated in FIG. 3A is configured according to a first one of the configurations described above, wherein the first and fourth switching elements are set to “closed” (e.g., they are configured to have reverse bias such that they exhibit high impedance to ground, illustrated by a connected arrow), while the second and third switching elements are set to “open” (e.g., they are configured to have forward bias such that they exhibit low impedance to ground, illustrated by an unconnected arrow), such that the first connection is enabled and the second connection is disabled. The fourth PIN diode switching element is connected to the “off” arm downstream from the second PIN diode switching element, to absorb incident signals that may otherwise reflect back to the second output port, thus reducing the reflectivity in the off arm of the switch.

When the first connection is disabled, the third switching element may shunt current through a first shunt path and reduce current reflections through the first output port (e.g., by dissipating power in the resistor). Conversely, when the second connection is disabled, the fourth switching element may shunt current through a second shunt path and reduce current reflections through the second output port. Advantageously, current reflections through the second output port when the second connection is disabled and current reflections through the first output port when the first connection is disabled may be reduced to below −20 dB for an octave range of frequency. The octave range of frequency that exhibits this reduced reflectivity may be selected based on an operating frequency of a device within which the solid-state switch is to be included, and the center frequency of this frequency range may be selected by adjusting electrical lengths of the transmission line elements of the solid-state switch.

In some embodiments, as shown in FIG. 3B, the solid-state switch is configurable to open the first and second switching elements and close the third and fourth switching elements to disable both the first connection between the input port and the first output port and the second connection between the input port and the second output port. In other words, both of the connections to the first and second output ports may be set to the off state, and signals incident on either the first or second output port are absorbed.

In some embodiments, each of the first, second, third, and fourth switching elements are configurable to be opened or closed by adjusting a voltage across the respective switching element to have forward bias or reverse bias, respectively.

In some embodiments, as shown in FIG. 2A, each of the switching elements may be followed a second companion switching element connected in series to the respective switching element. For example, the solid-state switch may further include a fifth switching element (e.g., D_{1B} of FIG. 2A) connected in series with the first switching element (e.g., D_{1A} of FIG. 2A), a sixth switching element (e.g., D_{2B}) connected in series with the second switching element (e.g., D_{2B}), a seventh switching element (e.g., D_{3B}) connected in series with the third switching element (e.g., D_{3A}), and an eighth switching element (e.g., D_{4B}) connected in series with the fourth switching element (e.g., D_{4A}). These companion switching elements may further reduce reflections and undesirable signal transfer in the solid-state switch. The companion switching elements may be configured to switch from forward and reverse bias in conjunction with their respective series-connected switching element. For example, the first and fifth switching elements may be configured to have the same bias, wherein both the first and fifth switching elements switch between forward and reverse bias simultaneously. The companion switching elements may further dampen reflections and suppress transmissions on an “off” portion of the solid-state switch circuit. Further, the companion switching elements may broaden the effective operating frequency range of the switch circuit.

FIGS. 4A-4B illustrate a model of switch performance using a shunting PIN diode switch topology, according to some embodiments. The results illustrated in FIGS. 4A-4B were obtained via simulation in Cadence Applied Wave Research (AWR) Microwave Office™ using a simplified model for linear circuits (e.g., resistors, capacitors, and transmission lines) and foundry models for nonlinear elements (e.g., PIN diodes). As illustrated, the proposed switch topology demonstrates low loss, high linearity, and high-power handling. Additionally, the topology of these embodiments exhibits an improved return loss over a wider frequency range on all ports and, in particular, on the “off port”, compared to current implementations. Specifically, FIG. 4A illustrates the reflectivity in decibels of output 2 (labeled S₃₃, solid line), output 1 (labeled S₂₂, short dashed line), and input 1 (labeled S₁₁, long dashed line). Further, FIG. 4B illustrates the gain in decibels from input 1 to output 1 (labeled S₂₁), and the isolation of output 2 from input 1 in decibels (labeled S₃₁), when the first connection is enabled and the second connection is disabled.

FIG. 5 illustrates a simplified PIN diode switch circuit diagram, enumerating exemplary characteristic impedances and electrical lengths for 8 different transmission lines of the circuit diagram. The electrical lengths in FIG. 5 are defined at the center of the band: (22.5 GHz+55 GHz)/2=38.75 GHz

FIG. 6 illustrates a simplified PIN diode switch circuit diagram, where the PIN diodes are replaced with ideal short circuits and open circuits to represent the low and high impedance states, according to some embodiments. FIG. 6 illustrates a similar switch topology to FIG. 2, but with some of the circuit elements abstracted out for simplicity.

FIG. 7 illustrates a model of switch performance according to the simplified circuit model of FIG. 5. The traces in FIG. 7 were calculated while the circuit is in the configuration where the first connection between the input (port 1) and the first output (port 2) is open, and the connection between the input (port 1) and the second output (port 3) is closed. In FIG. 5, traces labeled as “S_{XY}” refer to the power ratio, in decibels, of the power received at the x port to the power transmitted into the y port. For example, S₁₁ refers to the reflectivity at port 1, and S₂₁ refers to the ratio of power received at port 2 to power input to port 1. As illustrated, isolation is infinite since the low impedance PIN diodes are replaced with ideal short circuits. Further, the reflectivity at port 2 and port 3 remains well below −20 dB, and generally below −25 dB, for the octave frequency range from ˜23 GHz to ˜54 GHz.

FIG. 8 illustrates a layout of the gallium arsenide (GaAs) monolithic microwave integrated circuit (MMIC) with shunting PIN diode switch topology, to illustrate the practical implementation of the switch.

The switch topologies described herein offer advantages for test and measurement (T&M) systems that are used to test devices that are part of systems utilizing phased array antennas. These switch topologies may be implemented as standalone devices to be included in a T&M system, or as part of a T&M system, according to various embodiments. Typical devices are transceivers, beamformers, power amplifiers, as well as phased array antennas themselves. These devices are common in the areas of microwave and millimeter-wave mobile communications (5G) and radar systems.

Systems utilizing phased array antennas often have many ports and therefore T&M systems may also have many ports to test them. An economic way to build a T&M system with many microwave and millimeter-wave ports is typically to use switches to switch between the ports and route signals to and from a common receiver and transmitter, often a vector signal analyzer and vector signal generator, respectively.

The switch topologies illustrated by embodiments described herein enable switched test ports to have high power handling, high linearity, high isolation from adjacent ports, and to not reflect signals back into the device-under-test from “off” or unexcited test ports on the T&M system.

### FIG. 9—SPDT Switch in a 5G Test and Measurement System

FIG. 9 illustrates an example use case of a SPDT switch in a practical 5G test and measurement system, according to some embodiments. As illustrated, a single VSG and a single VSA are combined by an arrangement of SPDT switches and a pair of single-pole N+1 throw switches (“N+1 Switch”). The illustrated arrangement may demonstrate the following functionality:

1. The output of the VSG is connected to one of 2N ports (TRXK), where K is in the range of 1 to 2N.

2. One of the TRXK ports is connected to the input of the VSA

3. The output of the VSG is connected to the input of the VSA via the “Loopback” path.

In the illustrated embodiment, the VSA and the VSG are not connected to the same TRXK port simultaneously. Additionally, it should be noted that the N+1 switches may be constructed with a “tree” or cascade of SPDT switches, in various embodiments.

This test system (with N=3) may be used to test a typical 5G DUT such as Anokiwave™ AWMF-1051 which is a beamformer that has 6 ports (4 dual polarization antenna ports and two additional common ports for vertical and horizontal polarization). The IC has eight antenna ports that may be connected to four dual-pol antenna elements to support both horizontal and vertical polarizations in a phased array.

Additionally or alternatively, the test system illustrated in FIG. 9 (with N=9) may be used to test a typical 5G DUT such as Analog Devices™ ADMV4801, among other possibilities, which is a beamformer that has 18 ports (8 vertical polarization antenna ports, 8 horizontal polarization ports, and two common ports for vertical and horizontal polarization). The IC may have sixteen antenna ports that may be connected to eight dual-pole antenna elements to support both horizontal and vertical polarizations in a phased array.

### FIGS. 10A-B and 11A-B—Forward and Reverse-Biased PIN Diodes

FIGS. 10A-B and 11A-B are circuit diagrams that clarify how the voltage bias on a PIN diode affects the behavior of a switching element, according to various embodiments. Specifically, FIGS. 10A-B are circuit diagrams illustrating the functionality of a forward-biased shunt PIN diode in a switching element and FIGS. 11A-B are circuit diagrams illustrating the functionality of a reverse-biased shunt PIN diode in a switching element, according to some embodiments.

As illustrated in FIG. 10A, a forward biased PIN diode allows current to flow through the shunt arm of the switching element to ground. The circuit diagram of FIG. 10A corresponds to the simplified schematic illustration in FIG. 10B, where the switching element is shown to be “open”. Accordingly, a forward-based PIN diode results in an open switching element.

Conversely, FIG. 11A illustrates how a reverse-biased PIN diode blocks current from traveling to ground, thus allowing current to flow from the source to the load. The circuit diagram of FIG. 11A corresponds to the simplified schematic illustration in FIG. 11B, where the switching element is shown to be “closed”. Accordingly, a reverse-based PIN diode results in an closed switching element.

Although the paths/terminals are discussed with regard to inputs and outputs to provide clarity and consistency with regard to input/output (I/O) paths/terminals labeled as inputs (e.g., input 314) and outputs (e.g., outputs 316 and 318), in some embodiments, the resulting conductive path may be used to route signals in either direction (e.g., from outputs to inputs of from inputs to outputs).

Although the embodiments above have been described in considerable detail, numerous variations and modifications will become apparent to those skilled in the art once the above disclosure is fully appreciated. It is intended that the following claims be interpreted to embrace all such variations and modifications. Furthermore, note that the word “may” is used throughout this application in a permissive sense (e.g., having the potential to, being able to), not a mandatory sense (e.g., must). The term “include,” and derivations thereof, mean “including, but not limited to.” As used in this specification, the singular forms “a,” “an,” and “the” include plural referents unless the content clearly indicates otherwise. Thus, for example, reference to “a device” includes a combination of two or more devices.

We claim:

1. A low-reflectivity solid-state switch, comprising:
an input port configured to transmit an electronic signal;
a first conductive path connected to the input port and a first output port, wherein the first conductive path comprises a first positive-intrinsic-negative (PIN) diode switching element;
a second conductive path connected to the input port and a second output port, wherein the second conductive path comprises a second PIN diode switching element;
a first shunt path connected to the first conductive path, wherein the first shunt path comprises a third PIN diode switching element; and
a second shunt path connected to the second conductive path, wherein the second shunt path comprises a fourth PIN diode switching element.

2. The solid-state switch of claim 1,
wherein the solid-state switch is configurable to close the first and fourth PIN diode switching elements and open the second and third PIN diode switching elements to enable a first connection between the input port and the first output port and disable a second connection between the input port and the second output port, and
wherein the solid-state switch is configurable to close the second and third PIN diode switching elements and open the first and fourth PIN diode switching elements to disable the first connection and enable the second connection.

3. The solid-state switch of claim 2,
wherein, when the first connection is disabled, the third PIN diode switching element shunts current through the first shunt path and reduces current reflections through the first output port; and
wherein, when the second connection is disabled, the fourth PIN diode switching element shunts current through the second shunt path and reduces current reflections through the second output port.

4. The solid-state switch of claim 3,
wherein current reflections through the second output port when the second connection is disabled and current reflections through the first output port when the first connection is disabled are reduced to below −18 dB for an octave range of frequency.

5. The solid-state switch of claim 1,
wherein the solid-state switch is configurable to open the first and second PIN diode switching elements and close the third and fourth PIN diode switching elements to disable a first connection between the input port and the first output port and disable a second connection between the input port and the second output port.

6. The solid-state switch of claim 1,
wherein each of the first, second, third, and fourth PIN diode switching elements are configurable to be opened and closed by adjusting a voltage across the respective PIN diode switching element to comprise forward bias or reverse bias, respectively.

7. The solid-state switch of claim 1, further comprising:
a fifth PIN diode switching element in the first conductive path in series with the first PIN diode switching element;
a sixth PIN diode switching element in the second conductive path in series with the second PIN diode switching element;
a seventh PIN diode switching element in the first shunt path in series with the third PIN diode switching element; and
an eighth PIN diode switching element in the second shunt path in series with the fourth PIN diode switching element.

8. A low-reflectivity solid-state switch, comprising:
an input port configured to transmit an electronic signal;
a first output port and a second output port configured to receive the electronic signal;
a first switching element connected between the input port and the first output port;
a second switching element connected between the input port and the second output port;
a third switching element connected to a first conductive path between the first switching element and the first output port; and
a fourth switching element connected to a second conductive path between the second switching element and the second output port.

9. The solid-state switch of claim 8,
wherein the solid-state switch is configurable to close the first and fourth switching elements and open the second and third switching elements to enable a first connection for transmitting electronic signals between the input port and the first output port and disable a second connection for transmitting electronic signals between the input port and the second output port, and
wherein the solid-state switching element is configurable to close the second and third switching elements and open the first and fourth switching elements to disable the first connection and enable the second connection.

10. The solid-state switch of claim 9,
wherein, when the first connection is disabled, the third switching element shunts current through a first shunt path and reduces current reflections through the first output port; and
wherein, when the second connection is disabled, the fourth switching element shunts current through a second shunt path and reduces current reflections through the second output port.

11. The solid-state switch of claim 10,
wherein current reflections through the second output port when the second connection is disabled and current reflections through the first output port when the first connection is disabled are reduced to below −20 dB for an octave range of frequency.

12. The solid-state switch of claim 8,
wherein the solid-state switch is configurable to open the first and second switching elements and close the third and fourth switching elements to disable a first connection between the input port and the first output port and disable a second connection between the input port and the second output port.

13. The solid-state switch of claim 8,
wherein each of the first, second, third, and fourth switching elements are configurable to be opened or closed by adjusting a voltage across the respective switching element to comprise forward bias or reverse bias, respectively.

14. The solid-state switch of claim 8, further comprising:
a fifth switching element connected in series with the first switching element;
a sixth switching element connected in series with the second switching element;
a seventh switching element connected in series with the third switching element; and
an eighth switching element connected in series with the fourth switching element.

15. The solid-state switch of claim 8, wherein the first, second, third and fourth switching elements comprises positive-intrinsic-negative (PIN) diode switches.

16. A method for routing a signal, comprising:
receiving the signal at an input of a solid-state switch, wherein the solid-state switch comprises:
a first conductive path connected to the input and a first output, wherein the first conductive path comprises a first positive-intrinsic-negative (PIN) diode switching element;
a second conductive path connected to the input and a second output, wherein the second conductive path comprises a second PIN diode switching element;
a first shunt path connected to the first conductive path, wherein the first shunt path comprises a third PIN diode switching element; and
a second shunt path connected to the second conductive path, wherein the second shunt path comprises a fourth PIN diode switching element; and
transmitting the signal from the input to one of the first or second output ports, wherein the signal is transmitted to the first or second output port based at least in part on whether each of the first, second, third, and fourth PIN diode switching elements are configured as forward-bias or reverse-bias.

17. The method of claim 16,
wherein, when the signal is to be transmitted from the input to the first output, the first and fourth PIN diode switching elements are configured as reverse bias and the second and third PIN diode switching elements are configured as forward bias; and
wherein, when the signal is to be transmitted from the input to the second output, the second and third PIN diode switching elements are configured as reverse bias and the first and fourth PIN diode switching elements are configured as forward bias.

18. The method of claim 17,
wherein, when the signal is to be transmitted from the input to the first output, the fourth PIN diode switching element shunts current through the second shunt path and reduces current reflections through the second output port; and
wherein, when the signal is to be transmitted from the input to the second output, the third PIN diode switching element shunts current through the first shunt path and reduces current reflections through the first output port.

19. The method of claim 18,
wherein current reflections through the second output port when the signal is transmitted from the input to the first output and current reflections through the first output port when the signal is transmitted from the input to the second output are reduced to below −20 dB for an octave range of frequency.

20. The method of claim 1, wherein the solid-state switch further comprises:
a fifth PIN diode switching element in the first conductive path in series with the first PIN diode switching element;
a sixth PIN diode switching element in the second conductive path in series with the second PIN diode switching element;
a seventh PIN diode switching element in the first shunt path in series with the third PIN diode switching element; and
an eighth PIN diode switching element in the second shunt path in series with the fourth PIN diode switching element,
wherein the fifth, sixth, seventh, and eighth PIN diode switching elements are configured with a common voltage as the first, second, third, and fourth PIN diode switching elements, respectively.
